(19) United States
(12) Patent Application Publication
(10) Pub. No.: US 2010/0265687 A1
(43) Pub. Date: Oct. 21, 2010

(54) Assembling Unit For Use Inside Housings Of Luminous Signallers Arranged In Airport Areas

(75) Inventors: Gianni Facchini, San Carlo (Ferrara) (IT); Michele Romagnoli, Bologna (IT); Giovanni Cannistra', Bologna (IT)

Correspondence Address: WILLIAM J. SAPONE;COLEMAN SUDOL SAPONE P.C., 714 COLORADO AVENUE, BRIDGE PORT, CT, 06605, US

(73) Assignee: O.C.E.M. S.P.A., S. Giorgio di Piano (Bologna) (IT)

(21) Appl. No.: 12/747,552

(22) PCT Filed: Dec. 11, 2008
(86) PCT No.: PCT/IB08/03427

§ 371 Date: Jun. 11, 2010

(30) Foreign Application Priority Data
Dec. 14, 2007 (IT) BO2007A 000823

(51) Int. Cl. H05K 7/02

(52) U.S. Cl. 361/807

(57) ABSTRACT

Assembling unit for use inside housings of luminous signallers arranged in airport areas, comprising an electronic board (1) and at least an electronic or electro-mechanical switching component (4), which is connected to the electronic board (1) by means of electric connecting cables (10), which are flexible for damping mechanical vibrations directed towards the electronic switching component (4) in order to avoid the occurring of undesired switching. According to an aspect of the invention, the switching component (4) can comprise outside a protective material absorbing the impacts or a protective cap (5) or it can be immersed in a liquid which damps its oscillations originating as a consequence of the mechanical vibrations which reach the switching component (4) itself.

### FIELD OF THE INVENTION

The present invention relates to the technical field of luminous signallers used in airport areas, the luminous signallers being embedded at least partially in the ground or being elevated thereon; in particular, the invention relates to the assembling units fixed inside the housings of the above-mentioned luminous signallers, which units comprise one or more electronic boards to control, check and/or supply the light sources contained inside the same luminous signallers.

### DESCRIPTION OF THE KNOWN ART

As it is known, said signallers are made up of a shell defined by a lower portion or housing, which is for example embedded in the ground, and of a metal cap projecting from the ground in which there are provided, in one or more distinct seats, suitable prisms and lamps for lighting the surrounding area according to a predetermined solid angle.

In the portion embedded in the ground, it is positioned the power and controlling circuitry (this latter being usually mounted on a printed circuit) in order to supply the light sources and to check their operational status. The shell is completely realized of a material able to resist to the mechanical stresses occurring on the cap due to the passage or impact (in the landing step) of the front small wheel or of one of the rear wheels of the aircraft as well as the vibrations resulting thereby and broadly speaking resulting by the taxiing of the aircraft itself.

Currently, the components of the electronic board (on which it is integrated a portion or the whole power and controlling circuitry) are conventionally assembled and the electronic board itself is rigidly constrained to the housing of the shell by means of known fixing techniques (threaded couplings). However, the mechanical vibrations resulting by the taxiing and the impact of aircrafts, which propagate inside the shell of the luminous signaller, cause different drawbacks: in particular, there can occur undesired switching of the electronic or electro-mechanical switching components (for example relay) of the electronic board, and this can lead to a malfunctioning of the electronic board and/or to an unreliable functioning of the luminous signaller as a whole (for example: undesired switching on/off of the lamps of the luminous signaller).

### SUMMARY OF THE INVENTION

Therefore, an object of the present invention is to provide an assembling unit comprising the electronic board and the electronic or electro-mechanical switching components electrically connected to the electronic board, which unit solves the above-mentioned drawbacks, concerning the occurring of undesired switching of the switching components.

The above-mentioned object is achieved by means of an assembling unit for use inside housings of luminous signallers arranged in airport areas, which unit comprises at least an electronic board and one or more electronic or electro-mechanical switching components, each being connected to the electronic board by means of electric connecting cables, which connecting cables are flexible for damping the mechanical vibrations directed towards said electronic switching component in order to avoid the occurring of undesired switching.

Therefore, the electric cables connecting the switching components to the electronic board are flexible in order to damp the mechanical vibrations directed, by means of the electronic board, towards the switching components themselves, at least to a sufficient extent to avoid triggering of undesired switching of the switching components; according to the invention and advantageously, the mechanical vibrations propagating inside the luminous signaller as a consequence of the taxiing and the impact of the aircrafts on the runway do not affect the switching components functioning any more.

The electric cables connecting each switching component to the electronic board can be designed to support the corresponding switching component substantially in an upright position; this latter can oscillate in the air (fluctuate) as a consequence of the damped mechanical vibrations which however reach it by means of the electric connecting cables to the electronic board. Advantageously, the upright position taken by each switching component allows this latter to oscillate as a consequence of the mechanical vibrations (which are damped thanks to the specific characteristics of flexibility of the corresponding electric cables connecting the component to the board) which reach it, thus avoiding possible impacts against other components of the board or against the housing walls.

In addition to or as an alternative to providing that each switching component remains substantially in an upright position thanks to the specific characteristics of the electric connecting cables to the board, it is for example possible to provide a protective cap or the same which is applied to each switching component in order to absorb possible impacts between the switching component itself and the board or between the switching component and the components contained inside the housing or the walls of this latter.

According to an alternative embodiment it is provided that the switching components are each immersed inside a fluid substance contained in a receptacle connected to the inventive assembling unit, for example a liquid of determined viscosity, so that the oscillations the switching component is subjected to, which originate from the damped mechanical vibrations which reach the switching component itself by means of the electric connecting cables to the electronic board, can damp in a short time.

According to another aspect of the invention, the electronic board can be buried, even only partially, in a block of resinous material to increase the characteristics of stiffness of the electronic board; the material of the resinous block can be also insulating and moisture-proof.

The improved characteristics of stiffness associated with the use of the resinous block make the electronic board and the corresponding electronic components fixed thereto advantageously more reliable, because fixing results more stable and more efficient and therefore it is not compromised by the mechanical vibrations, the housings of the luminous signallers are subjected to in airport areas. This leads also to a longer life of the electronic board.

### BRIEF DESCRIPTION OF THE DRAWINGS

The features of the invention, not emerging from the preceding, will be better highlighted in the following, according to the claims and with reference to the appended drawings, in which:

FIG. 1 shows a cross sectional schematic view of a luminous signaller in which it is housed an assembling unit according to the invention comprising an electronic board buried in the resinous material;

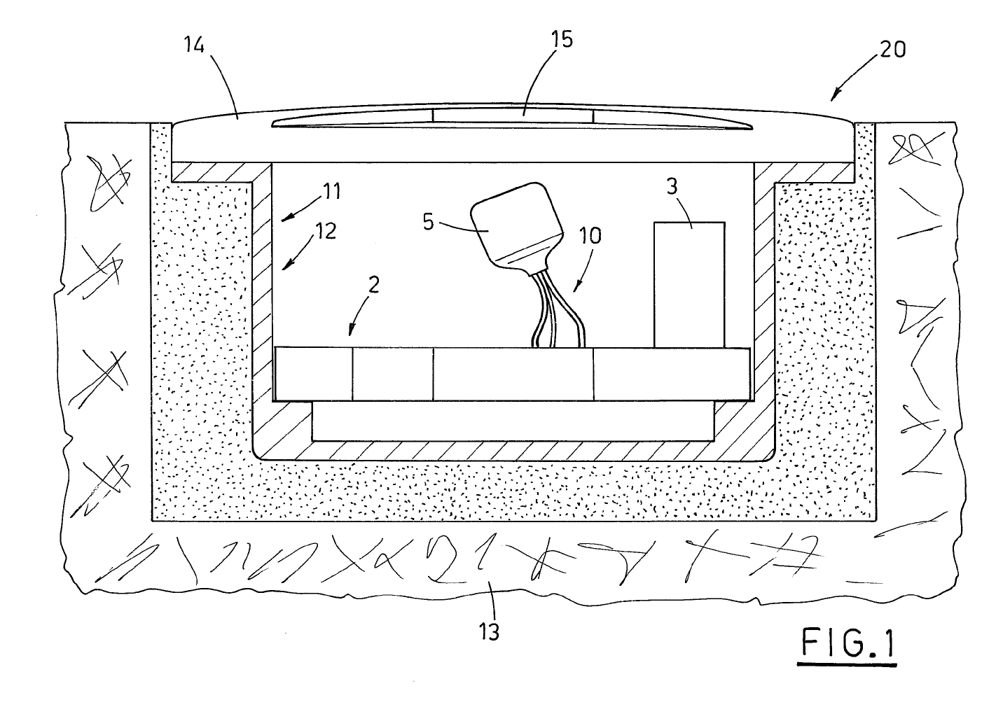

FIG. 2 shows a perspective schematic and in enlarged scale view of the electronic board according to the FIG. 1.

### DESCRIPTION OF PREFERRED EMBODIMENTS

Referring to the figures, the reference number 20 indicates a luminous signaller as a whole for use in airport areas and partially embedded in the ground, the luminous signaller being made up of: a shell 11 comprising a housing 12 apt to receive the inventive assembling unit 8; and a cap 14 where it is arranged at least a light source 15 of known kind.

The assembling unit 8 comprises an electronic board 1 (i.e. a printed circuit board, PCB) to which there are fixed electronic components 3, and switching components 4 (the example showing only one thereof, for simplicity).

The switching component 4 is for example a relay, an electronic or electro-mechanical switch or a bi-stable electronic switching component.

The electronic board 1 is buried in a stiffening block 2 of resinous material, having determined electric insulating properties, heat conducing properties and remarkable characteristics of moisture resistance; the stiffening block 2 is shaped in order to be restrained in the housing 12 of the shell 11 of the luminous signaller 20 and in order to be further stabilized with respect to the housing 12 by means of fixing means of known kind, which are not shown.

The reference number 30 indicates the electronic components mounted on the electronic board 1, which are completely buried inside the block 2, while the reference number 3 represents by way of example a component of the electronic board 1, which for its dimensions, contacts the resinous material only at the relative terminals (not shown) connecting to the electronic board 1; the connecting terminals of the electronic components 3, 30 are however buried in the resinous material constituting the block 2, thus improving the components 3, 30 fixing to the electronic board 1. The stiffening block 2 gives therefore to the electronic board 1 a mechanical stiffness which makes this latter more resistant and more reliable with respect to the mechanical vibrations, the luminous signaller 20 is subjected to.

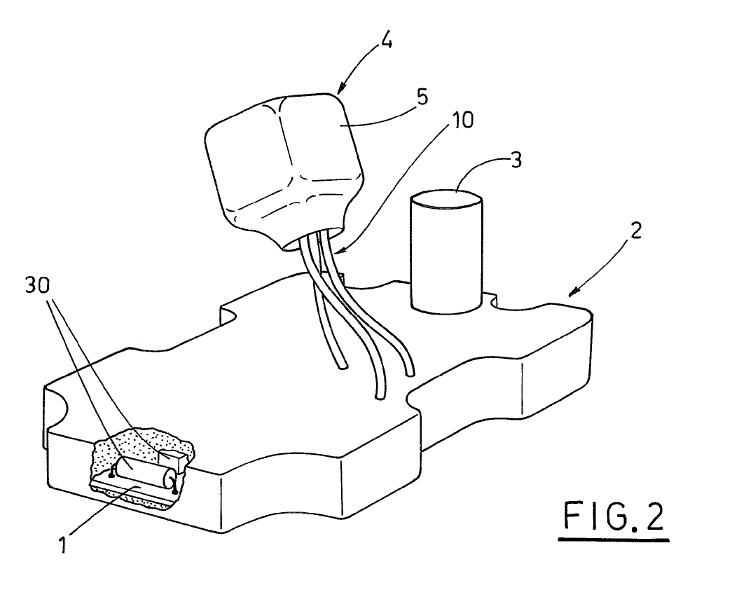

The example shown in FIG. 2 represents a switching component 4 connected to the electronic board 1 by means of electric connecting cables 10, which are only partially buried in the resinous material of the stiffening block 2; the electric cables 10 have determined characteristics of flexibility in order to damp the mechanical vibrations directed toward the same switching component 4 which propagate inside the housing 12.

The mechanical vibrations directed towards the switching component 4 damp therefore while travelling along the electric connecting cables 10 to the electronic board 1; as a consequence, there form mechanical oscillations in the switching component 4, which are of such small amplitude that they do not cause undesired switching in this latter. Such oscillations damp while time passes until they fade out, without consequences on the correct functioning of the switching component 4.

The electric cable 10 have therefore defined flexibility characteristics in order to damp the mechanical vibrations directed towards the switching component 4; moreover, the electric cables 10 are sufficiently stiff to maintain in a substantially upright position the switching component 4 also during the oscillations it is subjected to, so that it cannot strike for example the components 3, 30 of the electronic board 1 or the upper surface of the stiffening block 2 during the aforementioned mechanical oscillations. The component can therefore oscillate in the air, i.e. it can fluctuate, without striking elements of the assembling unit 8 or other elements contained inside the housing 12.

As an alternative or in addition to the protective measure against impacts of the switching component 4, just described concerning the specific characteristics of the corresponding electric connecting cables 10, a protective cap 5 against impacts is arranged on the switching component 4.

Therefore the protective cap 5 functions as protective element for the switching component 4 against the impacts it is subjected to, or it can be subjected to, as a consequence of its oscillations, however contained, resulting from the damped effect of the mechanical vibrations reaching the switching component 4 itself. However, as it has been precised above, a suitable dimensioning of the connecting cables 10 of the switching component 4 can guarantee an impact-free oscillation of this latter: in a similar hypothesis the usage of the protective cap becomes redundant.

As an alternative, the switching component 4 can be further provided with protection means against impacts, for example a coating or protective material applied outside the switching component 4 itself (not shown in the figures).

According to FIG. 2, the switching component 4 is arranged on the block 2 of resinous material, it remaining in a substantially upright position and being able to fluctuate.

According to a not shown variant, on the contrary the switching component 4 is arranged under the block 2 of resinous material and it is supported by this latter by means of electric cables 10 connecting to the electronic board 1. In this case, as a consequence of the force of gravity, the switching component 4 takes a stable balancing position around which it oscillates as a consequence of the damped mechanical vibrations reaching it; when said mechanical oscillations are damped to fading out, the switching component 4 comes back again to its stable balancing position.

As a further alternative to the usage of the protective cap 5 and/or electric cables 10 of determined stiffening characteristics (with reference to the embodiment shown in FIG. 2, in which the switching component 4 is arranged substantially uprightly) it is possible to immerse the switching component 4 for example in a liquid substance (or generally a fluid one) of determined viscosity contained inside a suitable container (solution not shown); the switching component 4 immersed in this liquid substance results therefore fluctuating and connected to the electronic board 1 by means of the above-mentioned electric cables 10. Each switching component 4 can be preferably arranged under the resinous block, so that it results supported by this latter and takes a stable balancing position as a consequence of the force of gravity.

The mechanical vibrations propagating inside the shell 11 are damped along the electric connecting cables 10 of the switching component 4 and the consequent mechanical oscillations triggering in the same switching component 4, which is immersed in the liquid substance, are damped to fading out. Therefore at the end of the vibratory phenomenon, the switching component 4 comes back to its stable balancing position, without being subjected neither to impacts nor to undesired switching.

The present description of a main embodiment and of variants of the invention refers explicitly to luminous signallers, which are embedded in the ground 13; similar considerations are as well valid for elevated luminous signallers arranged on the taxiing runway of the airports, which signallers are subjected to vibratory phenomena similar to the described ones as a function of the mounting heights and therefore of the vertical extension of their support arm.

It is intended that the preceding description is purely exemplary and not limiting, therefore possible practical variations are intended to fall in the protective scope of the invention, as defined by the preceding description and by the following claims.

1. Assembling unit for use inside housings of luminous signallers which are arranged in airport areas, comprising at least one electronic board (1) and at least one electronic or electro-mechanical switching component (4), which is connected to said electronic board (1) by means of electric connecting cables (10), said electric connecting cables (10) being flexible for damping the mechanical vibrations directed towards the above-mentioned electronic or electro-mechanical switching component (4) in order to avoid undesired switching.

2. Assembling unit according to claim 1, characterized in that said electric connecting cables (10) are designed to support said at least one electronic switching component (4) in a substantially upright position.

3. Assembling unit according to claim 1, characterized in that said connecting cables (10) are designed to allow said at least one electronic or electro-mechanical switching component (4) to fluctuate.

4. Assembling unit according to claim 1, further comprising at least one receptacle for containing a fluid, and said at least one electronic or electro-mechanical switching component (4) being at least partially insertable inside said receptacle, contacting said fluid so that oscillations said electronic or electro-mechanical switching component (4) is subjected to, and which originate as a consequence of mechanical vibrations which reach said at least one electronic or electro-mechanical switching component (4) damp are damped.

5. Assembling unit according to claim 1, characterized in that said at least one electronic or electro-mechanical switching component (4) has a protective material on an outside thereof for absorbing impacts which can occur as a consequence of the oscillations said electronic or electro-mechanical switching component (4) is subjected to and which originate as a consequence of mechanical vibrations which reach said at least one electronic or electro-mechanical switching component (4).

6. Assembling unit according to claim 5, characterized in that said protective material absorbing the impacts forms a protective cap (5).

7. Assembling unit according to claim 1, characterized in that said electronic board (1) is at least partially buried in a block (2) of resinous material to increase the stiffening characteristics of said electronic board (1), said electric connecting cables (10) of said at least one electronic or electro-mechanical switching component (4) coming out from said block (2) of resinous material.

8. Assembling unit according to claim 7, characterized in that the material constituting said resinous block (2) has determined insulating characteristics.

9. Assembling unit according to claim 7, characterized in that the material constituting said resinous block (2) has determined moisture resistant characteristics.

10. Assembling unit according to claim 7, characterized in that said block (2) of resinous material is shaped in order to be restrained in said housing (12).

11. Assembling unit according to claim 1, characterized in that said at least one electronic or electro-mechanical switching component (4) is a relay or an electronic or electro-mechanical switch or a bistable electronic switching component.

12. Assembling unit according to claim 2, characterized in that said connecting cables (10) are designed to allow said at least one electronic or electro-mechanical switching component (4) to fluctuate.

13. Assembling unit according to claim 8, characterized in that the material constituting said resinous block (2) has determined moisture resistant characteristics.
